(19) United States
(12) Patent Application Publication
(10) Pub. No.: US 2026/0101438 A1
(43) Pub. Date: Apr. 9, 2026

(54) WIRING BOARD AND MANUFACTURING METHOD FOR WIRING BOARD

(71) Applicant: Kyocera Corporation, Kyoto-shi (JP)

(72) Inventors: Tadashi NAGASAWA, Kyoto-shi (JP); Satoshi YOSHIURA, Kyoto-shi (JP); Takashi ISHIOKA, Kyoto-shi (JP)

(21) Appl. No.: 19/111,799

(22) PCT Filed: Sep. 22, 2023
(86) PCT No.: PCT/JP2023/034420

§ 371 Date: Mar. 14, 2025

(30) Foreign Application Priority Data
Sep. 27, 2022 (JP) 2022-154175

(51) Int. Cl. H05K 1/11; H05K 3/28; H05K 3/42

(52) U.S. Cl. CPC H05K 1/116; H05K 3/285; H05K 3/42; H05K 2201/0959; H05K 2203/1327

(57) ABSTRACT

A wiring board includes an insulation substrate including a through hole, an electrical conductor layer located on at least a part of an inner wall surface of the through hole and a surface of the insulation substrate, and an organic resin layer covering the insulation substrate and the electrical conductor layer. The organic resin layer includes a filling portion located in the through hole.

### CROSS-REFERENCE TO RELATED APPLICATIONS

This application is a US National Stage application, filed under 35 U.S.C. § 371, of International Application PCT/JP2023/034420, filed on Sep. 22, 2023, and claims priority to Japanese patent application 2022-154175, filed on Sep. 27, 2022, the entirety of the above listed applications is incorporated herein by reference.

### TECHNICAL FIELD

The present disclosure relates to a wiring board and a manufacturing method for the wiring board.

### BACKGROUND

A waveguide needs to be provided in a wiring board for communication, radar, or the like. For example, a through hole extending through the upper and lower surfaces of the wiring board is used as a waveguide as it is, or as described in JP 2010-251688 A, a through hole extending through the upper and lower surfaces of the wiring board is filled with a resin and used as a waveguide. When the through hole extending through the upper and lower surfaces of the wiring board is used as a waveguide as it is, an antenna board and a control board need to be separately prepared and assembled. On the other hand, when the through hole extending through the upper and lower surfaces of the wiring board is filled with a resin and used as a waveguide, the wiring board, the antenna board, and the control board can be integrated.

When the through hole extending through the upper and lower surfaces of the wiring board is filled with a resin and used as a waveguide, the resin is filled by, for example, a printing method. When the resin is filled by the printing method, voids are formed in the resin. Therefore, the dielectric constant becomes non-uniform and the loss due to reflection increases.

### SUMMARY

A wiring board according to embodiments of the present disclosure includes an insulation substrate including a through hole, an electrical conductor layer located on at least a part of an inner wall surface of the through hole and a surface of the insulation substrate, and an organic resin layer covering the insulation substrate and the electrical conductor layer. The organic resin layer includes a filling portion located in the through hole.

A manufacturing method for a wiring board according to embodiments of the present disclosure includes: preparing an insulation substrate including a through hole; forming an electrical conductor layer on at least a part of an inner wall surface of the through hole and a surface of the insulation substrate; covering the insulation substrate and the electrical conductor layer with an organic resin film; performing heating and pressurizing treatment to fill the through hole with a part of the organic resin film; and curing the organic resin film to form an organic resin layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosure. In the following description, various aspects of the disclosure are described with reference to the following drawings, in which:

FIG. 1 is an explanatory view for illustrating a main portion of a wiring board according to one embodiment of the present disclosure.

FIG. 2 is an explanatory view for illustrating a main portion of a wiring board according to another embodiment of the present disclosure.

### DESCRIPTION

As described above, when the through hole extending through the upper and lower surfaces of the wiring board is filled with a resin and employed as a waveguide, the resin is filled by, for example, a printing method. When the resin is filled by the printing method, voids are formed in the resin. Therefore, the dielectric constant becomes non-uniform and the loss due to reflection increases.

A wiring board according to an embodiment of the present disclosure has a configuration as described in the SUMMARY section above, and thus dielectric loss occurring in the through hole filled with a resin is reduced. According to a manufacturing method for a wiring board of the present disclosure, the formation of voids is reduced when the through hole is filled with a resin, by providing the configuration as described in the SUMMARY section above. Therefore, a wiring board, in which the through hole filled with the resin functions as a waveguide having a less dielectric loss, can be obtained.

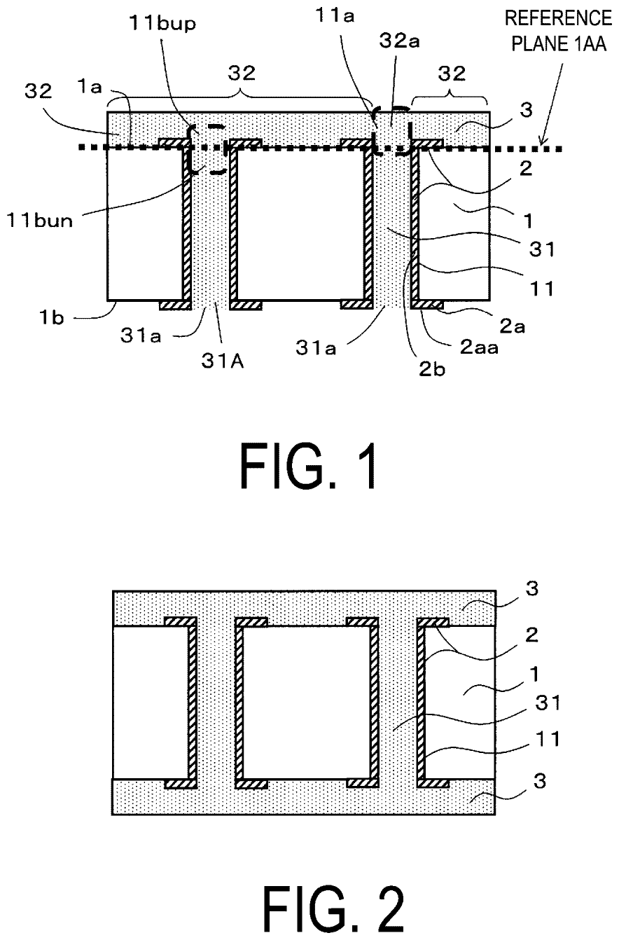

A wiring board according to one embodiment of the present disclosure will be described with reference to FIG. 1. FIG. 1 is an explanatory view for illustrating a main portion of the wiring board according to one embodiment of the present disclosure. Specifically, FIG. 1 illustrates the vicinity of a through hole 11 formed in an insulation substrate 1.

The insulation substrate 1 is not limited as long as it is made of a material having an insulation property. Examples of a material having an insulation property include resin and ceramic. Examples of the resin include an epoxy resin, a bismaleimide-triazine resin, a polyimide resin, a polyphenylene ether resin, and a liquid crystal polymer. These resins may be used alone or two or more kinds may be used in combination. Examples of the ceramic include alumina. The thickness of the insulation substrate 1 is not particularly limited, and is, for example, 0.2 mm or more and 3.0 mm or less.

The insulation substrate 1 may include an inorganic insulation filler. Examples of the inorganic insulation filler include silica, alumina, barium sulfate, talc, clay, glass, calcium carbonate, and titanium oxide. Single inorganic insulation filler may be used or two or more kinds may be used in combination.

The insulation substrate 1 may contain a reinforcing material. Examples of the reinforcing material include insulation fabric materials such as glass fibers, glass nonwoven fabrics, aramid nonwoven fabrics, aramid fibers, and polyester fibers. The reinforcing materials may be used alone or two or more kinds may be used in combination.

The insulation substrate 1 includes the through hole 11 extending from the upper surface to the lower surface. The through hole 11 is a hole for positioning an electrical conductor layer 2 in order to electrically connect the upper and lower surfaces of the insulation substrate 1. The number of through holes 11 is appropriately set in accordance with the size of the wiring board and the like. Normally, the number of through holes 11 included in one wiring board is 1000 or more and 30000 or less. The diameter of the through hole 11 is, for example, 200 μm or more and 2000 μm or less.

The electrical conductor layer 2 is located on at least a part of the inner wall surface of the through hole 11 and the surface of the insulation substrate 1. The electrical conductor layer 2 is not limited as long as it is an electrical conductor such as a metal. Specifically, the electrical conductor layer 2 is made of a metal foil such as a copper foil, a metal plating such as a copper plating, or the like. The thickness of the electrical conductor layer 2 is not particularly limited and is, for example, 20 μm or more and 40 μm or less, and the inner wall surface of the through hole 11 and the surface of the insulation substrate 1 may be different in thickness. The thickness of the electrical conductor layer 2 located on the inner wall surface of the through hole 11 may be, for example, 10 μm or more and 30 μm or less, and the thickness of the electrical conductor layer 2 located on the surface of the insulation substrate 1 may be, for example, 20 μm or more and 40 μm or less.

Here, a portion of the electrical conductor layer 2 located on a surface la of the insulation substrate 1 may be referred to as a surface electrical conductor layer 2a, and a portion of the electrical conductor layer 2 located on the inner wall surface of the through hole 11 may be referred to as a through hole electrical conductor layer 2b. In this wiring board, the surface electrical conductor layer 2a and the through hole electrical conductor layer 2b are integrally formed.

An organic resin layer 3 covers the surface of the insulation substrate 1 and the surface of the electrical conductor layer 2. The thickness of the organic resin layer 3 is not limited as long as it can cover the surface of the insulation substrate 1 and the surface of the electrical conductor layer 2. The thickness of the organic resin layer 3 is, for example, 0.025 mm or more and 0.2 mm or less.

Examples of the resin forming the organic resin layer 3 include, but are not limited to as long as it is an organic resin, cyclic olefin polymer, epoxy resin, bismaleimide-triazine resin, polyimide resin, polyphenylene ether resin, and liquid crystal polymer.

The cyclic olefin copolymer is a polyolefin-based copolymer having a cyclic structure. The cyclic olefin polymer includes not only a polymer using only one kind of cyclic olefin as a monomer but also a cyclic olefin copolymer obtained by polymerizing a cyclic olefin and another monomer copolymerizable with the cyclic olefin. A ratio of the cyclic olefin to another monomer is not particularly limited. For example, another monomer is used at a ratio of 2 parts by mass or more and 20 parts by mass or less with respect to 100 parts by mass of the cyclic olefin.

Examples of the cyclic olefin include a norbornene-based monomer, a cyclic diene-based monomer, and a vinyl alicyclic hydrocarbon-based monomer. Specific examples of the cyclic olefin include norbornene, vinylnorbornene, phenylnorbornene, dicyclopentadiene, tetracyclododecene, cyclopropene, cyclobutene, cyclopentene, cyclohexene, cyclohexadiene, and cyclooctadiene. These cyclic olefins may be used alone, or two or more kinds may be used in combination.

Examples of another monomer copolymerizable with the cyclic olefin may include a chain olefin, an acrylic acid, a methacrylic acid, an acrylic acid ester, a methacrylic acid ester, an aromatic vinyl compound, an unsaturated nitrile, and an aliphatic conjugated diene.

Specific examples of such a monomer may include ethylene, propylene, butene, acrylic acid, methacrylic acid, fumaric acid, fumaric anhydride, maleic acid, maleic anhydride, methyl acrylate, ethyl acrylate, propyl acrylate, isopropyl acrylate, methyl methacrylate, ethyl methacrylate, propyl methacrylate, isopropyl methacrylate, styrene, vinyl toluene, acrylonitrile, methacrylonitrile, 1, 3-butadiene, 2-methyl-1, 3-butadiene, and 2, 3-dimethyl-1,3-butadiene. These other monomers may be used alone or two or more kinds may be used in combination.

The organic resin layer 3 includes a filling portion 31 located in the through hole 11. That is, the through hole 11 is filled with a part of the organic resin layer 3 to form the filling portion 31. Since the filling portion 31 is a part of the organic resin layer 3, voids are less likely to be formed as compared with the case where the through hole 11 is separately filled with an organic resin. Therefore, the dielectric constant becomes uniform and the loss due to reflection can be reduced. Since the wiring board according to one embodiment includes the filling portion 31, the dielectric loss generated in the through hole 11 is reduced. As a result, the filling portion 31 located in the through hole 11 is used as an excellent waveguide.

In this case, when a portion of the organic resin layer 3 excluding the filling portion 31 is referred to as a covering portion 32, the filling portion 31 and the covering portion 32 may be made of the same material. The organic resin layer 3 is integrated from the covering portion 32 to the filling portion 31.

As illustrated in FIG. 1, a part (end portion 31a) of the filling portion 31 may protrude from a surface 1b of the insulation substrate 1. In FIG. 1, a protruding portion of the filling portion 31 is indicated as a protruding portion 31A. The protruding portion 31A is a portion located outside the surface 1b of the insulation substrate 1. A portion excluding the protruding portion 31A may be referred to as a body portion of the filling portion 31.

The protruding portion 31A may extend from the surface 1b of the insulation substrate 1 to a position of a surface 2aa outside the surface electrical conductor layer 2a. When the protruding portion 31A extends from the surface 1b of the insulation substrate 1 to the position of the surface 2aa outside the surface electrical conductor layer 2a, the filling portion 31 tends to have a high filling rate over the entire longitudinal direction of the through hole 11.

Even when a large number of through holes 11 are provided in the periphery of the main surface of the wiring board, the filling portion 31 having a small difference in filling rate can be obtained easily over the entire region of the periphery of the main surface of the wiring board. When printing using a paste, since the paste is applied in one direction, a difference in pressures is likely to occur on the surface la of the insulation substrate 1. On the other hand, in the method of pressing and heating the organic resin film, the surface la of the insulation substrate 1 is pressed all at once. Therefore, a difference in pressures is unlikely to occur at the surface la of the insulation substrate 1.

The organic resin layer 3 may be made of only an organic resin such as the above-described cyclic olefin polymer, or may contain an inorganic filler at a predetermined ratio in an organic resin. The content of the inorganic filler may be a volume ratio of 10 or more and 70 or less when the volume of the organic resin layer 3 is 100.

The organic resin layer 3 may contain a flame retardant and a weathering stabilizer in addition to the inorganic filler. In this case, the content of the flame retardant contained in the organic resin layer 3 may be larger than the content of the weathering stabilizer. The inorganic filler and the flame retardant may be present in the same amount. The weathering stabilizer may be unevenly distributed in the surface portion of the organic resin layer 3.

When the organic resin layer 3 contains the inorganic filler, the flame retardant and the weathering stabilizer at the same time, the reliability of mechanical strength, flame retardancy, moisture resistance, thermal resistance and the like of the wiring board including the organic resin layer 3 can be enhanced.

The volume ratios of the organic resin, the inorganic filler, the flame retardant, and the weathering stabilizer contained in the organic resin layer 3 can be obtained from, for example, an electron microscope obtained by photographing a cross section of the wiring board. In this case, first, each component included in a region to be imaged (for example, 5 μm×5 μm to 20 μm×20 μm) is identified by an analyzer attached to the electron microscope. Next, the contour of each component is determined on the taken photograph. The total area of the contour is then determined for each component. Next, the total area of each component is divided by the surface area of the photographed region to obtain the area ratio of each component. The area ratio thus obtained is defined as the volume ratio in the organic resin layer 3.

In at least one example, the organic resin layer 3 is integrally formed from the surface la of the insulation substrate 1 to the filling portion 31 located in the through hole 11. In other words, for example, the filling portion 31 extending from the covering portion 32 located on the insulation substrate 1 and the electrical conductor layer 2 to the inside of the through hole 11 is an integral body. In at least one example, there is no interface between the covering portion 32 and the filling portion 31.

“There is no interface” means that the covering portion 32 and the filling portion 31 are made of the same material, and something like a boundary is not recognized between the covering portion 32 and the filling portion 31 even when confirmed by an electron microscope. That is, it means that a different kind of material other than the materials forming the covering portion 32 and the filling portion 31 is not present between the covering portion 32 and the filling portion 31. Therefore, the material forming the covering portion 32 is continuously present from the covering portion 32 to the filling portion 31 in the through hole 11, and forms a structure of the same material.

When a portion of the covering portion 32 located on the through hole 11 is defined as a hole covering portion 32a, in at least one example, there is no interface between the hole covering portion 32a and the filling portion 31. The relationship between the hole covering portion 32a and the filling portion 31 is, for example, the same as the relationship between the covering portion 32 and the filling portion 31. As described above, the absence of an interface means that the hole covering portion 32a and the filling portion 31 are made of the same material, and something like a boundary is not recognized between the hole covering portion 32a and the filling portion 31 even when confirmed by an electron microscope. That is, there is no different material other than the materials forming the hole covering portion 32a and the filling portion 31 between the hole covering portion 32a and the filling portion 31. Therefore, the material forming the hole covering portion 32a continuously exists from the hole covering portion 32a to the filling portion 31 in the through hole 11, and forms a structure of the same material.

In the organic resin layer 3, the covering portion 32 which is a portion of the surface la of the insulation substrate 1, the filling portion 31 located in the through hole 11, and the hole covering portion 32a located directly above the through hole 11 are, in at least one example, integrally formed. In at least one example, there is no material other than the material forming the organic resin layer 3 between the covering portion 32 located on the surface la of the insulation substrate 1 and the filling portion 31 located in the through hole 11. The material forming the organic resin layer 3 means the organic resin constituting the organic resin layer 3.

When the organic resin layer 3 contains an inorganic filler such as silica particles in addition to the organic resin, this means that the components and the ratio (composition) of the organic resin and the inorganic filler are the same from the hole covering portion 32a to the filling portion 31. In this case, the fact that the components of the organic resin are the same means that, for example, the main polymers constituting the organic resin are the same.

“The same inorganic filler” means, for example, that the metal oxide of the inorganic filler is the same. The inorganic filler is identified by, for example, atomic absorption spectrometry, X-ray diffraction, or X-ray fluorescence. “The ratio (composition) of the organic resin and the inorganic filler is the same” means that the volume ratio of the organic resin among the filling portion 31, the covering portion 32, and the hole covering portion 32a is within ±5%.

In the organic resin layer 3, for example, no material other than the material forming the organic resin layer 3 exists between the filling portion 31 located in the through hole 11 and the hole covering portion 32a located on a directly upper portion 11a of the through hole 11. In at least one example, there is no interface between the covering portion 32 located on the surface la of the insulation substrate 1 and the hole covering portion 32a located on the directly upper portion 11a of the through hole 11. In at least one example, the organic resin layer 3 does not have an interface where different materials are in contact with each other on an extension line 1aa along the surface la of the insulation substrate 1. In at least one example, the organic resin layer 3 has no material other than the material forming the organic resin layer 3 on the extension line 1aa along the surface la of the insulation substrate 1.

The fact that there is no interface on the extension line 1aa along the surface la of the insulation substrate 1 or there is no material other than the material forming the organic resin layer 3 on the extension line 1aa along the surface la of the insulation substrate 1 means that when the extension line 1aa along the surface la of the insulation substrate 1 is defined as a reference plane, there is no interface caused by a different member or a different material in the region of the reference plane.

The region of the reference plane includes an upper region 11bup and a lower region 11bun when the reference plane is set as a boundary. That is, the interface is a boundary at which substances containing different main components or substances having different compositions are adjacent to each other. In this case, it means that the substances containing different main components or the substances having different compositions are not adjacent to each other.

The interface may extend in the thickness direction of the organic resin layer 3, and may extend from one surface to the other surface of the organic resin layer 3. The interface extending in the thickness direction of the covering portion 32 may also extend from one surface to the other surface of the covering portion 32. The interface between the filling portion 31 and the hole covering portion 32a may also extend over the entire radial direction of the hole covering portion 32a.

In the organic resin layer 3, the orientations of the inorganic filler and the flame retardant may be different between the filling portion 31 located in the through hole 11 and the hole covering portion 32a located in the directly upper portion 11a of the through hole 11. For example, the degree of orientation of the inorganic filler contained in the filling portion 31 located in the through hole 11 may be higher than the degree of orientation of the inorganic filler contained in the hole covering portion 32a located immediately above the through hole 11.

When the organic resin layer 3 including the filling portion 31 is formed on the surface la of the insulation substrate 1 and in the through hole 11, the density of the filling portion 31 may be different between the vicinity of the surface la of the insulation substrate 1 and the center portion of the insulation substrate 1 in the thickness direction, when the diameter of the through hole 11 is small (300 μm or less), for example. The density of the filling portion 31 may be different between both surfaces of the insulation substrate 1. “The density of the filling portion 31 may be different” means that a portion having a partially different density may be present in the filling portion 31.

In this case, the difference in the density of the filling portion 31 is, for example, evaluated based on the area ratio of voids observed when the outer surface or the inner cross section of the filling portion 31 is observed. This is because, as will be described later, the wiring board is manufactured by adopting a method in which the organic resin layer 3 is disposed on one surface of the insulation substrate 1 and a treatment of pressurizing and heating is performed. That is, the filling portion 31 in the wiring board is formed by disposing a sheet-shaped organic resin film on the surface la of the insulation substrate 1 and pressing and heating the organic resin film, whereby a part of the organic resin film enters the through hole 11. Therefore, the method is different from a method of filling a paste containing an organic resin by a printing method.

The sheet-shaped organic resin film has a higher viscosity than a paste containing an organic resin. In the method in which the through hole 11 is filled with the organic resin film, since the organic resin film has high viscosity, the organic resin film is likely to receive a high shear stress (shear stress) between the organic resin film and the electrical conductor layer 2 formed on the inner wall of the through hole 11 at the time of filling the through hole 11. As a result, in the filling portion 31, portions having different densities and degrees of orientation are likely to be formed in the through hole 11.

At least one of the density and the degree of orientation of the filling portion 31 is likely to change also in the radial direction. The difference in the density of the filling portion 31 may be dealt with by obtaining the difference in the porosity. As for the porosity of the filling portion 31, a method is used in which the side surface of the filling portion 31 is observed, the porosities of the center and the end portions in the longitudinal direction are obtained, and the difference therebetween is evaluated. The difference in the degree of orientation in the filling portion 31 is, for example, evaluated from the difference in the direction of the inorganic filler. A metal microscope or a digital microscope may be used to evaluate the degree of orientation of the inorganic filler. This is because when a metal microscope or a digital microscope is used, light is applied to a sample to be observed and a shape based on the reflected light is obtained.

The degree of orientation of the inorganic filler included in the filling portion 31 may be higher on the side surface side in the radial direction than on the center side in the radial direction. The “longitudinal direction of the through hole 11” corresponds to the thickness direction of the insulation substrate 1 of the through hole 11. In FIG. 1, the “radial direction of the through hole 11” corresponds to a direction perpendicular to the longitudinal direction of the through hole 11.

The shear stress applied to the organic resin film is also caused by the material or surface roughness of each member described below. The surface la of the insulation substrate 1, the directly upper portion 11a of the through hole 11, and the surface of the electrical conductor layer 2 disposed on the surface la of the insulation substrate 1 or the surface of the electrical conductor layer 2 in the through hole 11 are made of different materials. The surface la of the insulation substrate 1, the directly upper surface 11a of the through hole 11, and the surface of the electrical conductor layer 2 disposed on the surface la of the insulation substrate 1 or the surface of the electrical conductor layer 2 in the through hole 11 may have different surface roughnesses.

The reason why the directly upper portion 11a of the through hole 11 is made of different material from that of the surface la of the insulation substrate 1 and the surface of the electrical conductor layer 2 is that the directly upper portion 11a of the through hole 11 is a space where no member exists in the middle of the manufacturing step. Therefore, shear stress is basically less likely to act on the organic resin layer 3 at the directly upper portion 11a of the through hole 11. On the other hand, since the electrical conductor layer 2 disposed inside the through hole 11 is present in the through hole 11, shear stress applied to the organic resin layer 3 mainly depends on the surface state of the inner wall of the electrical conductor layer 2.

Next, a manufacturing method for the wiring board according to the present disclosure will be described. According to an embodiment of the present disclosure, the manufacturing method for the wiring board includes the following steps (a) to (e).
(a) Step of preparing an insulation substrate including a through hole.
(b) Step of forming an electrical conductor layer on at least a part of an inner wall surface of the through hole and a surface of the insulation substrate.
(c) Step of covering the insulation substrate and the electrical conductor layer with an organic resin film.
(d) Step of performing heating and pressurizing treatment to fill the through hole with a part of the organic resin film.
(e) Step of curing the organic resin film to form an organic resin layer.

First, in the step (a), the insulation substrate 1 including the through hole 11 is prepared. The insulation substrate 1 is as described above, and thus a detailed description thereof will be omitted.

Next, in the step (b), the electrical conductor layer 2 is formed on at least a part of the inner wall surface of the through hole 11 and the surface of the insulation substrate 1. As described above, the electrical conductor layer 2 is not limited as long as it is an electrical conductor such as a metal. Specifically, the electrical conductor layer 2 is made of a metal foil such as a copper foil, or a metal plating such as a copper plating, or the like. Specifically, the electrical conductor layer 2 is formed by attaching a metal foil such as a copper foil or precipitating a metal such as copper by plating.

Next, in the step (c), the insulation substrate 1 and the electrical conductor layer 2 are covered with an organic resin film. The organic resin film becomes the organic resin layer 3 after being cured in the step (e) described later. Therefore, examples of the resin forming the organic resin film include the above-described organic resins, and a detailed description thereof will be omitted.

The size and shape of the organic resin film are not limited. For example, the shape of the organic resin film and the shape of the insulation substrate 1 may be substantially the same in a plan view. When the shape of the organic resin film and the shape of the insulation substrate 1 are substantially the same, the same organic resin film is present in any region on the insulation substrate 1, and unevenness in dielectric constant does not occur. As a result, impedance matching is facilitated.

As the organic resin film, an organic resin film may be used that has a complex melt viscosity so that the frequency dependence of the complex melt viscosity at 110° C. is 1×10⁴ Pas or more and 1×10⁶ Pas or less in the frequency range of 0.1 rad/s or more and 100 rad/s or less. By using such an organic resin film, the through hole 11 can be stably filled with the resin.

Next, in the step (d), the organic resin film is subjected to heating and pressurizing treatment to fill a part of the organic resin film into the through hole 11. The heating temperature is appropriately set according to the organic resin film to be used, and may be, for example, a temperature at which the organic resin film is softened and a part of the softened organic resin film can enter the through hole 11. The pressurization condition may be, for example, 1.0 MPa or more and 5.0M Pa or less.

Specifically, when the lowest melting temperature of the organic resin film is a ° C., the organic resin film may be heated at a C. +20° C. By heating at such a temperature, the softened organic resin film is less likely to flow out to the outer peripheral portion of the insulation substrate 1 even when pressurized. The softened organic resin film can be filled in the through hole 11 with almost no void. As a result, the dielectric constant is likely to be uniform, and the loss due to reflection can be reduced.

The heating and pressurizing treatment may be performed in a reduced pressure atmosphere. By performing heating and pressurizing treatment under the reduced pressure atmosphere, when the organic resin film is embedded from both sides, voids are less likely to occur in the organic resin film filled in the through hole 11. As a result, the dielectric constant can be made constant and reflection is less likely to occur.

Finally, in the step (e), the organic resin film is cured to form the organic resin layer 3. The curing method is appropriately selected depending on the organic resin film to be used. When a thermosetting organic resin film is used, it is cured by heat treatment. When a thermoplastic organic resin film is used, it is heated to fill the through hole 11, and then the temperature is lowered to room temperature to cure it.

By this step, formation of voids is reduced when the through hole is filled with resin. As a result, the wiring board according to an embodiment of the present disclosure is obtained in which the through hole filled with the resin is caused to function as a waveguide having low dielectric loss.

In the wiring board specifically obtained by the above steps, when a portion of the organic resin layer excluding the filling portion is defined as a covering portion, an analysis confirmed that the filling portion and the covering portion are made of the same material.

There is no interface between the covering portion and the filling portion. That is, when a portion of the covering portion located on the through hole is defined as a hole covering portion, there is no interface between the hole covering portion and the filling portion. In the manufactured wiring board, a part of the filling portion protrudes from the surface of the insulation substrate opposite to the surface on which the organic resin layer is disposed. In some of the plurality of wiring boards manufactured, in all the through holes formed in the surface of the wiring board, a part of the filling portion is found to protrude from the surface of the insulation substrate opposite to the surface on which the organic resin layer is disposed.

The wiring board according to the present disclosure is not limited to the above-described embodiment. In the wiring board according to the above-described embodiment, the organic resin layer 3 is located on one surface of the insulation substrate 1. However, as in the wiring board according to another embodiment illustrated in FIG. 2, the organic resin layer 3 may be located on both surfaces of the insulation substrate 1.

The wiring board in which the organic resin layer 3 is located on both surfaces of the insulation substrate 1 as illustrated in FIG. 2 may be subjected to the heating and pressurizing treatment with both surfaces of the insulation substrate 1 covered with an organic resin film. Alternatively, the wiring board may be subjected to the heating and pressurizing treatment with one surface of the insulation substrate 1 covered with the organic resin film, and then the wiring board may be subjected to the heating and pressurizing treatment with the other surface covered with the organic resin film.

An embodiment of the present disclosure has been described above. However, the present disclosure is not limited to the above-described embodiment, and various modifications and improvements are possible within the scope of the present disclosure illustrated in (1) to (6) below.
(1) A wiring board according to an embodiment of the present disclosure includes an insulation substrate including a through hole, an electrical conductor layer located on at least a part of an inner wall surface of the through hole and a surface of the insulation substrate, and an organic resin layer covering the insulation substrate and the electrical conductor layer. The organic resin layer includes a filling portion located in the through hole.

With regard to the embodiment of the present disclosure, the following embodiments (2) to (5), and (7) to (10) will be further disclosed.
(2) In the wiring board according to (1), when a portion of the organic resin layer other than the filling portion is defined as a covering portion, the filling portion and the covering portion are made of the same material.
(3) In the wiring board according to (2), no interface exists between the covering portion and the filling portion.
(4) In the wiring board according to (2) or (3), when a portion of the covering portion located on the through hole is defined as a hole covering portion, no interface exists between the hole covering portion and the filling portion.
(5) In the wiring board according to any one of (1) to (4), a part of the filling portion protrudes from the surface of the insulation substrate.
(6) A manufacturing method for a wiring board according to the present disclosure includes: preparing an insulation substrate including a through hole; forming an electrical conductor layer on at least a part of an inner wall surface of the through hole and a surface of the insulation substrate; covering the insulation substrate and the electrical conductor layer with an organic resin film; performing heating and pressurizing treatment to fill the through hole with a part of the organic resin film; and curing the organic resin film to form an organic resin layer.
(7) In the manufacturing method according to (6), a shape of the organic resin film and a shape of the insulation substrate are substantially the same in a plan view.
(8) In the manufacturing method according to (6) or (7), the organic resin film has a complex melt viscosity so that frequency dependence of the complex melt viscosity at 110° C. is 1×10⁴ Pas or more and 1×10⁶ Pas or less in a frequency range of 0.1 rad/s or more and 100 rad/s or less.
(9) In the manufacturing method according to any one of (6) to (8), when a lowest melting temperature of the organic resin film is a ° C., the heating and pressurizing treatment is performed in a range of a ° C.±20° C.
(10) In the manufacturing method according to any one of (6) to (9), the heating and pressurizing treatment is performed under a reduced pressure atmosphere.

### REFERENCE SIGNS

1 Insulation substrate
11 Through hole
2 Electrical conductor layer
3 Organic resin layer
31 Filling portion
32 Covering portion

1. A wiring board comprising:
an insulation substrate comprising a through hole;
an electrical conductor layer located on at least a part of an inner wall surface of the through hole and a surface of the insulation substrate; and
an organic resin layer covering the insulation substrate and the electrical conductor layer,
wherein the organic resin layer comprises a filling portion located in the through hole.

2. The wiring board according to claim 1, wherein when a portion of the organic resin layer other than the filling portion is defined as a covering portion, the filling portion and the covering portion are made of the same material.

3. The wiring board according to claim 2, wherein no interface exists between the covering portion and the filling portion.

4. The wiring board according to claim 2, wherein when a portion of the covering portion located on the through hole is defined as a hole covering portion, no interface exists between the hole covering portion and the filling portion.

5. The wiring board according to claim 1, wherein a part of the filling portion protrudes from the surface of the insulation substrate.

6. A manufacturing method for a wiring board comprising:
preparing an insulation substrate comprising a through hole;
forming an electrical conductor layer on at least a part of an inner wall surface of the through hole and a surface of the insulation substrate;
covering the insulation substrate and the electrical conductor layer with an organic resin film;
performing heating and pressurizing treatment to fill the through hole with a part of the organic resin film; and
curing the organic resin film to form an organic resin layer.

7. The manufacturing method for a wiring board according to claim 6, wherein a shape of the organic resin film and a shape of the insulation substrate are substantially the same in a plan view.

8. The manufacturing method for a wiring board according to claim 6, wherein the organic resin film has a complex melt viscosity so that frequency dependence of the complex melt viscosity at 110° C. is between 1×10⁴ Pas and 1×10⁶ Pas within a frequency range of 0.1 rad/s to 100 rad/s.

9. The manufacturing method for a wiring board according to claim 6, wherein the heating and pressurizing treatment is performed within ±20° C. of a lowest melting temperature of the organic resin film.

10. The manufacturing method for a wiring board according to claim 6, wherein the heating and pressurizing treatment is performed under a reduced pressure atmosphere.
